(19) United States
(12) Patent Application Publication
(10) Pub. No.: US 2022/0169827 A1
(43) Pub. Date: Jun. 2, 2022

(54) RESIN MATERIAL AND MULTILAYER PRINTED WIRING BOARD

(71) Applicant: SEKISUI CHEMICAL CO., LTD., Osaka (JP)

(72) Inventors: Akiko KUBO, Ibaraki (JP); Tatsushi HAYASHI, Ibaraki (JP); Yuko KAWAHARA, Ibaraki (JP); Susumu BABA, Ibaraki (JP)

(73) Assignee: SEKISUI CHEMICAL CO., LTD., Osaka (JP)

(21) Appl. No.: 17/441,516

(22) PCT Filed: Mar. 27, 2020
(86) PCT No.: PCT/JP2020/013985

§ 371 Date: Sep. 21, 2021

(30) Foreign Application Priority Data
Mar. 27, 2019 (JP) 2019-061451

(51) Int. Cl. C08K 3/36; H05K 1/03

(52) U.S. Cl. CPC C08K 3/36; H05K 1/0373; H05K 1/036; H05K 2201/0209; H05K 2201/0129

(57) ABSTRACT

Provided is a resin material capable of suppressing warpage of a cured product and shortening the baking time. The resin material according to the present invention contains a thermosetting compound that does not have an aromatic ring in a structural portion excluding a thermosetting functional group, has two or more CH₃ terminals in a structural portion excluding a thermosetting functional group, and satisfies the following formula (X); and an inorganic filler, the resin material having a content of the inorganic filler of 30 wt % or more in 100 wt % of components excluding a solvent in the resin material: 0.1≤A/(B×C)≤0.6 . . . Expression (X) A: number of CH₃ terminals of a structural portion excluding a thermosetting functional group of the thermosetting compound, B: number of thermosetting functional groups of the thermosetting compound, and C: number of carbon atoms of a structural portion excluding a thermosetting functional group of the thermosetting compound.

### TECHNICAL FIELD

The present invention relates to a resin material containing a thermosetting compound. The present invention also relates to a multilayer printed wiring board using the resin material.

### BACKGROUND ART

Conventionally, various resin materials have been used to obtain electronic components such as semiconductor devices, laminated plates, and printed wiring boards. For example, in a multilayer printed wiring board, resin materials are used for forming an insulating layer for insulation between layers in the inside thereof or forming an insulating layer located in a surface layer portion. The insulating layer generally includes wiring which is metal and laminated on the surface thereof. In addition, in order to form the insulating layer, a resin film obtained by forming the resin material into a film may be used. The resin material and the resin film are used as an insulating material or the like for a multilayer printed wiring board including a build-up film.

Patent Document 1 below discloses a resin composition containing (A) a monofunctional epoxy resin having a biphenyl structure and (B) a curing agent.

Patent Document 2 below discloses a resin composition containing (A) an epoxy resin having an ester backbone, (B) an active ester curing agent, and (C) an inorganic filler.

In this resin composition, when the content of the nonvolatile component in the resin composition is 100 mass %, the content of the inorganic filler (C) is 50 mass % or more, and when the content of the inorganic filler (C) is 100 parts by mass, the content of the epoxy resin having an ester backbone (A) is 1 to 20 parts by mass.

### RELATED ART DOCUMENT

Patent Document
Patent Document 1: JP 2018-095749 A
Patent Document 2: JP 2014-177530 A

### SUMMARY OF THE INVENTION

### Problems to be Solved by the Invention

In a process of producing a printed wiring board or the like, a resin material is cured to form an insulating layer (cured product of the resin material). In addition, in a process of producing a printed wiring board or the like, before mounting an electronic component or the like, a baking treatment (heat treatment) is performed for the purpose of sufficiently removing moisture and a solvent contained in the insulating layer. If this baking treatment is insufficient, swelling occurs between the insulating layer and the metal layer in a reflow process performed at the time of mounting the electronic component or the like. In the conventional resin materials as described in Patent Documents 1 and 2, moisture and a solvent are hardly removed from the insulating layer, and the baking time may be long. For this reason, when a printed wiring board or the like is produced using a conventional resin material, the productivity may be deteriorated.

In addition, in the conventional resin material, warpage of a cured product of the resin material may occur. In particular, in the conventional resin material containing an epoxy compound having an aromatic ring as described in Patent Document 1, warpage of the cured product is more likely to occur. When warpage occurs in the cured product, warpage also occurs in the circuit board and the metal layer in association with the cured product, and as a result, the yield decreases.

In recent years, in order to achieve high-speed communication with an increase in the amount of information transmission, multilayering, upsizing, and finer wiring of a printed wiring board or the like have been advanced, and warpage of a cured product is more likely to occur, and the baking time is longer.

An object of the present invention is to provide a resin material capable of suppressing warpage of a cured product and shortening the baking time. Another object of the present invention is to provide a multilayer printed wiring board using the resin material.

### Means for Solving the Problems

According to a broad aspect of the present invention, there is provided a resin material containing: a thermosetting compound that does not have an aromatic ring in a structural portion excluding a thermosetting functional group, has two or more CH₃ terminals in a structural portion excluding a thermosetting functional group, and satisfies the following formula (X); and an inorganic filler, the resin material having a content of the inorganic filler of 30 wt % or more in 100 wt % of components excluding a solvent in the resin material.

0.1≤A/(B×C)≤0.6 Expression (X)

A: number of CH terminals of a structural portion excluding a thermosetting functional group of the thermosetting compound

B: number of thermosetting functional groups of the thermosetting compound

C: number of carbon atoms of a structural portion excluding a thermosetting functional group of the thermosetting compound

In a specific aspect of the resin material according to the present invention, the thermosettirng compound has a tert-butyl group in a structural portion excluding a thermosetting functional group, and the thermosetting compound has one or more tert-butyl groups in a structural portion excluding a thermosetting functional group.

In a specific aspect of the resin material according to the present invention, the thermosetting compound has 5 or more and 30 or less carbon atoms in a structural portion excluding a thermosetting functional group.

In a specific aspect of the resin material according to the present invention, the thermosetting compound has one or two thermosetting functional groups.

In a specific aspect of the resin material according to the present invention, the thermosetting compound has one thermosetting functional group.

In a specific aspect of the resin material according to the present invention, the structural portion excluding a thermosetting functional group of the thermosetting compound has a branched structure.

In a specific aspect of the resin material according to the present invention, the structural portion excluding a thermosetting functional group of the thermosetting compound has a branched structure, and a proportion of number of carbon atoms of a chain having a maximum number of atoms of the structural portion excluding a thermosetting functional group of the thermosetting compound in 100% of number of carbon atoms of the structural portion excluding a thermosetting functional group of the thermosetting compound is 40% or more and 90% or less.

In a specific aspect of the resin material according to the present invention, the resin material is a resin film.

The resin material according to the present invention is suitably used for forming an insulating layer in a multilayer printed wiring board.

According to a broad aspect of the present invention, there is provided a multilayer printed wiring board including a circuit board, a plurality of insulating layers disposed on a surface of the circuit board, and a metal layer disposed between the plurality of insulating layers, at least one of the plurality of insulating layers being a cured product of the resin material.

### Effect of the Invention

The resin material according to the present invention contains a thermosetting compound that does not have an aromatic ring in a structural portion excluding a thermosetting functional group, has two or more CH₃ terminals in the structural portion excluding a thermosetting functional group, and satisfies the formula (X), and an inorganic filler. In the resin material according to the present invention, the content of the inorganic filler is 30 wt % or more in 100 wt % of components excluding a solvent in the resin material. Since the resin material according to the present invention has the above-described configuration, warpage of the cured product can be suppressed, and the baking time can be shortened.

### BRIEF DESCRIPTION OF DRAWING

FIG. 1 is a cross-sectional view schematically illustrating a multilayer printed wiring board using a resin material according to an embodiment of the present invention.

### MODE(S) FOR CARRYING OUT THE INVENTION

Hereinafter, the present invention will be described in detail.

The resin material according to the present invention contains a thermosetting compound that does not have an aromatic ring in a structural portion excluding a thermosetting functional group, has two or more CH₃ terminals in the structural portion excluding a thermosetting functional group, and satisfies the following formula (X), and an inorganic filler. Hereinafter, the “thermosetting compound that does not have an aromatic ring in a structural portion excluding a thermosetting functional group, has two or more CH₃ terminals in the structural portion excluding a thermosetting functional group, and satisfies the following formula (X)” may be referred to as a first thermosetting compound. The first thermosetting compound is a thermosetting component.

0.1≤A/(B×C)≤0.6 Expression (X)

A: the number of CH₃ terminals of the structural portion excluding a thermosetting functional group of the first thermosetting compound

B: the number of thermosetting functional groups of the first thermosetting compound

C: the number of carbon atoms of the structural portion excluding a thermosetting functional group of the first thermosetting compound

In the resin material according to the present invention, the content of the inorganic filler is 30 wt % or more in 100 wt %, of components excluding a solvent in the resin material.

Since the resin material according to the present invention has the above-described configuration, warpage of the cured product can be suppressed, and the baking time can be shortened.

In addition, since the resin material according to the present invention has the above-described configuration, the dielectric loss tangent of the cured product can be reduced. The resin material according to the present invention is excellent in reflow resistance.

In a conventional resin material, it is difficult to suppress warpage of a cured product and shorten the baking time. In particular, in a resin material in which an inorganic filler is blended or a resin material in which a thermosetting compound having an aromatic ring is blended, it is difficult to suppress warpage of a cured product and shorten the baking time.

On the other hand, in the resin material according to the present invention, although the resin material contains an inorganic filler, the specific first thermosetting compound is contained, so that the baking time can be shortened. In the resin material according to the present invention, an electronic component such as a printed wiring board can be favorably formed even when the baking time is shortened.

The resin material according to the present invention may contain two or more types of thermosetting compounds. The resin material according to the present invention may contain a thermosetting compound different from the first thermosetting compound. Hereinafter, the “thermosetting compound different from the first thermosetting compound” may be referred to as a second thermosetting compound. The second thermosetting compound is a thermosetting component.

The resin material according to the present invention may be a resin composition or a resin film. The resin composition has fluidity. The resin composition may be in the form of a paste. The paste contains a liquid. From the viewpoint of excellent handleability, the resin material according to the present invention is preferably a resin film.

The resin material according to the present invention is preferably a thermosetting material. When the resin material is a resin film, the resin film is preferably a thermosetting resin film.

Hereinafter, details of each component used in the resin material according to the present invention, the use of the resin material according to the present invention, and the like will be described.

[First Thermosetting Compound]

The resin material according to the present invention contains the first thermosetting compound. The first thermosetting compound is a thermosetting compound not having an aromatic ring in a structural portion excluding a thermosetting functional group. The first thermosetting compound is a thermosetting compound having two or more CH % terminals in the structural portion excluding a thermosetting functional group. The first thermosetting compound is a thermosetting compound satisfying the formula (X). Since the first thermosetting compound does not have an aromatic ring in the structural portion excluding a thermosetting functional group, the elastic modulus of the insulating layer can be improved, so that warpage of the cured product can be effectively suppressed. In addition, since the first thermosetting compound satisfies the (X), the baking time can be effectively shortened, and the dielectric loss tangent of the cured product can be lowered. The first thermosetting compound is not required to be a curing agent. Only one type of the first thermosetting compound may be used, or two or more types thereof may be used in combination.

The first thermosetting compound does not have an aromatic ring in the structural portion excluding a thermosetting functional group. The first thermosetting compound does not have, for example, a benzene ring, a naphthalene ring, an anthracene ring, a phenanthrene ring, a tetracene ring, a chrysene ring, a triphenylene ring, a tetraphene ring, a pyrene ring, a pentacene ring, a picene ring, and a perylene ring in the structural portion excluding a thermosetting functional group.

The first thermosetting compound may have an aliphatic ring in the structural portion excluding a thermosetting functional group. The aliphatic ring may have a double bond in a part of the ring.

Examples of the thermosetting functional group include an epoxy group, a maleimide group, a benzoxazine group, a cyanate group, a phenolic hydroxyl group, and an active ester group. The first thermosetting compound may be an epoxy compound, a maleimide compound, a benzoxazine compound, a cyanate compound, a phenol compound, or an active ester compound.

The epoxy group may be a glycidyl ester group, a glycidyl ether group, or an alicyclic epoxy group. When the epoxy group is a glycidyl ester group, the structural portion excluding a thermosetting functional group means a structural portion excluding a glycidyl ester group. When the epoxy group is a glycidyl ether group, the structural portion excluding a thermosetting functional group means a structural portion excluding a glycidyl ether group. When the epoxy group is an alicyclic epoxy group, the structural portion excluding a thermosetting functional group means a structural portion excluding two carbon atoms and one oxygen atom which form an oxacyclopropane structure.

The thermosetting functional group of the first thermosetting compound is preferably an epoxy group or a maleimide group. From the viewpoint of improving thermosetting properties, the first thermosetting compound is preferably an epoxy compound or a maleimide compound.

From the viewpoint of exhibiting the effect of the present invention, the first thermosetting compound is a thermosetting compound satisfying the following formula (X).

0.1≤A/(B×C)≤0.6 Expression (X)

A: the number of CH₃ terminals of the structural portion excluding a thermosetting functional group of the first thermosetting compound

B: the number of thermosetting functional groups of the first thermosetting compound

C: the number of carbon atoms of the structural portion excluding a thermosetting functional group of the first thermosetting compound

In the formula (X), the value of “A/(B×C)” is 0.1 or more and 0.6 or less. In the formula (X), the value of “A/(B×C)” is preferably 0.2 or more and preferably 0.5 or less. When the value of “A/(B×C)” is the above lower limit or more and the above upper limit or less, the effect of the present invention can be more effectively exhibited.

Since the first thermosetting compound has two or more CH₃ terminals in the structural portion excluding a thermosetting functional group, A in the formula (X) is two or more. The number of CH₃ terminals (A in the formula (X)) of the structural portion excluding a thermosetting functional group of the first thermosetting compound is preferably 3 or more, and more preferably 4 or more, but preferably 15 or less and more preferably 10 or less. When the number of CH₃ terminals is the above lower limit or more and the above upper limit or less, the effect of the present invention can be more effectively exhibited, and the solubility of the first thermosetting compound in the resin material can be enhanced.

Since the first thermosetting compound has a thermosetting functional group, B in the formula (X) is one or more. The number of thermosetting functional groups (B in the formula (X)) of the first thermosetting compound may be one, two, two or more, three, or three or more. From the viewpoint of more effectively exhibiting the effect of the present invention, the number of thermosetting functional groups of the first thermosetting compound is preferably one or two, and more preferably one. The first thermosetting compound is preferably a monofunctional or bifunctional thermosetting compound, and more preferably a monofunctional thermosetting compound.

The number of carbon atoms (C in the formula (X)) in the structural portion excluding a thermosetting functional group of the first thermosetting compound is preferably 5 or more, and more preferably 8 or more, but preferably 40 or less, more preferably 30 or less, and further preferably 20 or less. When the number of carbon atoms is the above lower limit or more and the above upper limit or less, the effect of the present invention can be more effectively exhibited. When the number of carbon atoms is the above upper limit or less, the solubility of the first thermosetting compound in the resin material can be enhanced.

The first thermosetting compound may have an atom other than carbon in the structural portion excluding a thermosetting functional group, or may not have an atom other than carbon.

The first thermosetting compound may or may not have a silicon atom. The first thermosetting compound preferably does not have a silicon atom.

From the viewpoint of effectively exhibiting the effect of the present invention, the first thermosetting compound preferably has a tert-butyl group in the structural portion excluding a thermosetting functional group. When the first thermosetting compound has a tert-butyl group in the structural portion excluding a thermosetting functional group, the number of CH₃ terminals (A in the formula (X)) of the structural portion excluding a thermosetting functional group of the first thermosetting compound is three or more.

The number of the tert-butyl groups in the structural portion excluding a thermosetting functional group of the first thermosetting compound is preferably one or more. When the number of the tert-butyl groups is the above lower limit or more, the effect of the present invention can be more effectively exhibited.

From the viewpoint of effectively exhibiting the effect of the present invention and lowering the dielectric loss tangent of the cured product, the structural portion excluding a thermosetting functional group of the first thermosetting compound preferably has a branched structure.

The proportion of the number of carbon atoms of a chain having the maximum number of atoms of the structural portion excluding a thermosetting functional group of the first thermosetting compound in 100% of the number of carbon atoms of the structural portion excluding a thermosetting functional group of the first thermosetting compound is preferably 40% or more, and more preferably 50% or more, but preferably 90% or less, and more preferably 80% or less. When the proportion is the above lower limit or more and the above upper limit or less, the effect of the present invention can be more effectively exhibited, and the dielectric loss tangent of the cured product can be further lowered.

From the viewpoint of effectively exhibiting the effect of the present invention, the molecular weight of the structural portion excluding a thermosetting functional group of the first thermosetting compound is preferably 100 or more, and more preferably 110 or more, but preferably 400 or less, and more preferably 300 or less.

The molecular weight of the structural portion excluding a thermosetting functional group of the first thermosetting compound means a molecular weight that can be calculated from the structural formula when the first thermosetting compound is not a polymer and when the structural formula of the first thermosetting compound can be specified.

From the viewpoint of effectively exhibiting the effect of the present invention, the molecular weight of the first thermosetting compound is preferably 150 or more, and more preferably 200 or more, but preferably 600 or less, and more preferably 500 or less.

The molecular weight of the first thermosetting compound means a molecular weight that can be calculated from the structural formula when the first thermosetting compound is not a polymer and when the structural formula of the first thermosetting compound can be specified. When the first thermosetting compound is a polymer, the molecular weight of the first thermosetting compound indicates a weight average molecular weight in terms of polystyrene measured by gel permeation chromatography (GPC).

The content of the first thermosetting compound is preferably 0.5 wt % or more, more preferably 1 wt % or more, and further preferably 2 wt % or more, but preferably 30 wt % or less, and more preferably 25 wt % or less in 100 wt % of components excluding a solvent in the resin material. When the content of the first thermosetting compound is the above lower limit or more and the above upper limit or less, the effect of the present invention can be more effectively exhibited, and the dielectric loss tangent of the cured product can be further lowered.

The content of the first thermosetting compound is preferably 1 wt % or more, more preferably 3 wt % or more, further preferably 5 wt % or more, and particularly preferably 10 wt % or more in 100 wt % of components excluding an inorganic filler and a solvent in the resin material. The content of the first thermosetting compound is preferably 80 wt % or less, more preferably 70 wt % or less, further preferably 60 wt % or less, particularly preferably 60 wt % or less, and most preferably 50 wt % or less in 100 wt % of components excluding an inorganic filler and a solvent in the resin material. When the content of the first thermosetting compound is the above lower limit or more and the above upper limit or less, the effect of the present invention can be more effectively exhibited, and the dielectric loss tangent of the cured product can be further lowered.

### [Second Thermosetting Compound]

The resin material preferably contains the second thermosetting compound. The second thermosetting compound may be a thermosetting compound having an aromatic ring in the structural portion excluding a thermosetting functional group. The second thermosetting compound may be a thermosetting compound not having a CH₃ terminal, or having one CH₃ terminal in the structural portion excluding a thermosetting functional group. The second thermosetting compound may be a thermosetting compound not satisfying the formula (X). The second thermosetting compound may be a thermosetting compound satisfying the following formula (Y1) or a thermosetting compound satisfying the following formula (Y2). The second thermosetting compound is not required to be a curing agent. The second thermosetting compound may be a curing agent. Only one type of the second thermosetting compound may be used, or two or more types thereof may be used in combination.

A′/(B′×C′)<0.1 Expression (Y1)

A′/(B′×C′)>0.6 Expression (Y2)

In the formula (Y1) and the formula (Y2), A′, B′, and C′ mean the following.

A′: the number of CH₃ terminals of the structural portion excluding a thermosetting functional group of the second thermosetting compound

B′: the number of thermosetting functional groups of the second thermosetting compound

C′: the number of carbon atoms of the structural portion excluding a thermosetting functional group of the second thermosetting compound

Examples of the second thermosetting compound include an epoxy compound, a maleimide compound, a phenol compound, an active ester compound, a cyanate ester compound, a benzoxazine compound, a carbodiimide compound, an acid anhydride, an amine compound, a thiol compound, a phosphine compound, a dicyandiamide, a vinyl compound, a styrene compound, a phenoxy compound, an oxetane compound, a polyarylate compound, a diallyl phthalate compound, an acrylate compound, an episulphide compound, a (meth)acrylic compound, an amino compound, an unsaturated polyester compound, a polyurethane compound, and a silicone compound.

The second thermosetting compound preferably contains at least one type of thermosetting compound among an epoxy compound, a maleimide compound, a vinyl compound, a phenol compound, an active ester compound, a cyanate ester compound, a benzoxazine compound, a carbodiimide compound, and an acid anhydride. The second thermosetting compound more preferably contains at least one type of thermosetting compound among an epoxy compound, a maleimide compound, a phenol compound, an active ester compound, a cyanate ester compound, a benzoxazine compound, and a carbodiimide compound. The second thermosetting compound further preferably contains at least an epoxy compound. In this case, the dielectric loss tangent of the cured product can be further lowered, and the thermal dimensional stability of the cured product can be further enhanced.

In the second thermosetting compound, “the phenol compound, the active ester compound, the cyanate ester compound, the benzoxazine compound, the carbodiimide compound, and the acid anhydride” are generally a curing agent. Therefore, in the present specification, “the phenol compound, the active ester compound, the cyanate ester compound, the benzoxazine compound, the carbodiimide compound, and the acid anhydride” may be described as “curing agent”.

Hereinafter, the epoxy compound, the maleimide compound, the vinyl compound, the phenol compound, the active ester compound, the cyanate ester compound, the benzoxazine compound, the carbodiimide compound, the acid anhydride, the amine compound, the thiol compound, the phosphine compound, and the dicyandiamide, which are the second thermosetting compound, will be described in more detail.

### <Epoxy Compound>

As the epoxy compound, a conventionally known epoxy compound can be used. The epoxy compound is an organic compound having at least one epoxy group. Only one type of the epoxy compound may be used, or two or more types thereof may be used in combination.

Examples of the epoxy compound include a bisphenol A type epoxy compound, a bisphenol F type epoxy compound, a bisphenol S type epoxy compound, a phenol novolac type epoxy compound, a biphenyl type epoxy compound, a biphenyl novolac type epoxy compound, a biphenol type epoxy compound, a naphthalene type epoxy compound, a fluorene type epoxy compound, a phenol aralkyl type epoxy compound, a naphthol aralkyl type epoxy compound, a dicyclopentadiene type epoxy compound, an anthracene type epoxy compound, an epoxy compound having an adamantane backbone, an epoxy compound having a tricyclodecane backbone, a naphthylene ether type epoxy compound, and an epoxy compound having a triazine nucleus in the backbone.

The epoxy compound may be a glycidyl ether compound. The glycidyl ether compound is a compound having at least one glycidyl ether group.

From the viewpoint of further lowering the dielectric loss tangent and enhancing the thermal dimensional stability and flame retardancy of the cured product, the epoxy compound preferably contains an epoxy compound having an aromatic backbone, preferably contains an epoxy compound having a naphthalene backbone or a phenyl backbone, and is more preferably an epoxy compound having an aromatic backbone.

From the viewpoint of further lowering the dielectric loss tangent and improving the linear expansion coefficient (CTE) of the cured product, the epoxy compound preferably contains an epoxy compound that is liquid at 25° C. and an epoxy compound that is solid at 25° C.

The viscosity at 25° C. of the epoxy compound that is liquid at 25° C. is preferably 1,000 mPa·s or less, and more preferably 500 mPa·s or less.

The viscosity of the epoxy compound can be measured using, for example, a dynamic viscoelasticity measuring apparatus (“VAR-100” manufactured by REOLOGICA Instruments AB).

The molecular weight of the epoxy compound is more preferably 1,000 or less. In this case, even when the content of the inorganic filler is 50 wt or more in 100 wt % of components excluding a solvent in the resin material, a resin material having high fluidity during formation of the insulating layer is obtained. Therefore, when an uncured product or a B-stage product of the resin material is laminated on the circuit board, the inorganic filler can be uniformly present.

The molecular weight of the epoxy compound means a molecular weight that can be calculated from the structural formula when the epoxy compound is not a polymer and when the structural formula of the epoxy compound can be specified. When the epoxy compound is a polymer, the molecular weight means a weight average molecular weight.

From the viewpoint of further enhancing the thermal dimensional stability of the cured product, the content of the epoxy compound is preferably 4 wt % or more, and more preferably 7 wt % or more, but preferably 15 wt % or less, and more preferably 12 wt % or less in 100 wt % of components excluding a solvent in the resin material.

The content of the epoxy compound is preferably 15 wt % or more, and more preferably 25 wt or more, but preferably 50 wt % or less, and more preferably 40 wt % or less in 100 wt % of components excluding an inorganic filler and a solvent in the resin material. When the content of the epoxy compound is the above lower limit or more and the above upper limit or less, the thermal dimensional stability of the cured product can be further enhanced.

The weight ratio of the content of the epoxy compound to the total content of the first thermosetting compound and the curing agent (the content of the epoxy compound/the total content of the first thermosetting compound and the curing agent) is preferably 0.2 or more, and more preferably 0.3 or more, but preferably 0.9 or less, and more preferably 0.8 or less. When the weight ratio is the above lower limit or more and the above upper limit or less, the dielectric loss tangent can be further lowered and the thermal dimensional stability can be further enhanced.

### <Maleimide Compound>

As the maleimide compound, a conventionally known maleimide compound can be used. Only one type of the maleimide compound may be used, or two or more types thereof may be used in combination.

The maleimide compound may be a bismaleimide compound.

Examples of the maleimide compound include N-phenylmaleimide and N-alkylbismaleimide.

The maleimide compound preferably has a backbone derived from a diamine compound other than a dimer diamine or a triamine compound other than a trimer triamine.

The maleimide compound may or may not have an aromatic ring. The maleimide compound preferably has an aromatic ring.

In the maleimide compound, a nitrogen atom in the maleimide backbone is preferably bonded to an aromatic ring.

From the viewpoint of further enhancing the thermal dimensional stability of the cured product, the content of the maleimide compound is preferably 0.5 wt % or more, and more preferably 1 wt % or more, but preferably 15 wt % or less, and more preferably 10 wt % or less in 100 wt % of components excluding a solvent in the resin material.

The content of the maleimide compound is preferably 2.5 wt % or more, more preferably 5 wt % or more, and further preferably 7.5 wt % or more, but preferably 50 wt % or less, and more preferably 35 wt % or less in 100 wt % of components excluding an inorganic filler and a solvent in the resin material. When the content of the maleimide compound is the above lower limit or more and the above upper limit or less, the thermal dimensional stability of the cured product can be further enhanced.

From the viewpoint of effectively exhibiting the effect of the present invention, the molecular weight of the maleimide compound is preferably 500 or more, and more preferably 1,000 or more, but preferably less than 30,000, and more preferably less than 20,000.

The molecular weight of the maleimide compound means a molecular weight that can be calculated from the structural formula when the maleimide compound is not a polymer and when the structural formula of the maleimide compound can be specified. When the maleimide compound is a polymer, the molecular weight of the maleimide compound indicates a weight average molecular weight in terms of polystyrene measured by gel permeation chromatography (GPC).

Examples of commercially available products of the maleimide compound include “BMI-4000” and “BMI-5100” manufactured by Daiwa Kasei Industry Co., Ltd., and “BMI-3000” manufactured by Designer Molecules Inc.

### <Vinyl Compound>

As the vinyl compound, a conventionally known vinyl compound can be used. The vinyl compound is an organic compound having at least one vinyl group. Only one type of the vinyl compound may be used, or two or more types thereof may be used in combination.

Examples of the vinyl compound include divinylbenzyl ether compounds.

The content of the vinyl compound is preferably 5 wt % or more, more preferably 10 wt % or more, and further preferably 20 wt % or more, but preferably 80 wt % or less, and more preferably 70 wt % or less in 100 wt % of components excluding an inorganic filler and a solvent in the resin material. When the content of the vinyl compound is the above lower limit or more and the above upper limit or less, the thermal dimensional stability of the cured product can be further enhanced.

### <Phenol Compound>

Examples of the phenol compound include novolac type phenol, biphenol type phenol, naphthalene type phenol, dicyclopentadiene type phenol, aralkyl type phenol, and dicyclopentadiene type phenol.

Examples of commercially available products of the phenol compound include novolac type phenol (“TD-2091” manufactured by DIC Corporation), biphenyl novolac type phenol (“MEH-7851” manufactured by Meiwa Plastic Industries, Ltd.), an aralkyl type phenol compound (“MEH-7800” manufactured by Meiwa Plastic Industries, Ltd.), and phenols having an aminotriazine backbone (“LA-1356” and “LA-3018-50P” manufactured by DIC Corporation).

### <Active Ester Compound>

The active ester compound refers to a compound containing at least one ester bond in the structure and having an aliphatic chain, an aliphatic ring, or an aromatic ring bonded to both sides of the ester bond. The active ester compound is obtained, for example, by a condensation reaction of a carboxylic acid compound or a thiocarboxylic acid compound with a hydroxy compound or a thiol compound. Examples of the active ester compound include a compound represented by the following formula (1).

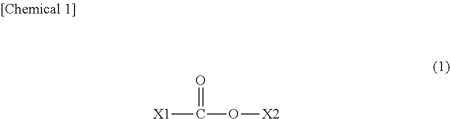

In the formula (1), X1 represents a group containing an aliphatic chain, a group containing an aliphatic ring, or a group containing an aromatic ring, and X2 represents a group containing an aromatic ring. Preferable examples of the group containing an aromatic ring include a benzene ring optionally having a substituent, and a naphthalene ring optionally having a substituent. Examples of the substituent include a hydrocarbon group. The number of carbon atoms in the hydrocarbon group is preferably 12 or less, more preferably 6 or less, and further preferably 4 or less.

Examples of the combination of X1 and X2 in the formula (1) include a combination of a benzene ring optionally having a substituent and a benzene ring optionally having a substituent, and a combination of a benzene ring optionally having a substituent and a naphthalene ring optionally having a substituent. Further, examples of the combination of X1 and X2 in the formula (1) include a combination of a naphthalene ring optionally having a substituent and a naphthalene ring optionally having a substituent.

The active ester compound is not particularly limited. From the viewpoint of further enhancing the thermal dimensional stability and the flame retardancy, the active ester compound is preferably an active ester compound having two or more aromatic backbones. From the viewpoint of lowering the dielectric loss tangent of the cured product and enhancing the thermal dimensional stability of the cured product, the active ester compound more preferably has a naphthalene ring in the main chain backbone. From the viewpoint of further shortening the baking time, the active ester compound is preferably an active ester compound having three or more functional groups. From the viewpoint of more effectively suppressing warpage of the cured product, the resin material preferably contains an active ester compound having two or more functional groups and an active ester compound having three or more functional groups. The functional group is preferably an active ester group.

The equivalent of the active ester is preferably 200 or more, but preferably 450 or less, more preferably 400 or less, and further preferably 350 or less. When the equivalent of the active ester is the above lower limit or more and the above upper limit or less, the baking time can be further shortened.

Examples of commercially available products of the active ester compound include “HPC-8000-65T”, “HPC-8000L-651MT”, “EXB9416-70BK”, “HPC-8150-62T”, “HPC-8900-70BK”, and “EXB8100-65T” manufactured by DIC Corporation.

### <Cyanate Ester Compound>

Examples of the cyanate ester compound include a novolac type cyanate ester resin, a bisphenol type cyanate ester resin, and a prepolymer obtained by partially trimerizing these resins. Examples of the novolac type cyanate ester resin include a phenol novolac type cyanate ester resin and an alkylphenol type cyanate ester resin. Examples of the bisphenol type cyanate ester resin include a bisphenol A type cyanate ester resin, a bisphenol E type cyanate ester resin, and a tetramethylbisphenol F type cyanate ester resin.

Examples of commercially available products of the cyanate ester compound include phenol novolac type cyanate ester resins (“PT-30” and “PT-60” manufactured by Lonza Japan Ltd.), and prepolymers obtained by trimerizing a bisphenol type cyanate ester resin (“BA-230S”, “BA-3000S”, “BTP-1000S”, and “BTP-6020S” manufactured by Lonza Japan Ltd.).

The content of the cyanate ester compound is preferably 10 wt % or more, more preferably 15 wt % or more, and further preferably 20 wt % or more, but preferably 85 wt % or less, and more preferably 75 wt % or less in 100 wt % of components excluding an inorganic filler and a solvent in the resin material. When the content of the cyanate ester compound is the above lower limit or more and the above upper limit or less, the thermal dimensional stability of the cured product can be further enhanced.

### <Benzoxazine Compound>

Examples of the benzoxazine compound include P-d type benzoxazine and F-a type benzoxazine.

Examples of commercially available products of the benzoxazine compound include “P-d type” manufactured by Shikoku Chemicals Corporation.

The content of the benzoxazine compound is preferably 1 wt % or more, more preferably 5 wt % or more, and further preferably 10 wt % or more, but preferably 70 wt % or less, and more preferably 60 wt % or less in 100 wt % of components excluding an inorganic filler and a solvent in the resin material. When the content of the benzoxazine compound is the above lower limit or more and the above upper limit or less, the thermal dimensional stability of the cured product can be further enhanced.

### <Carbodiimide Compound>

The carbodiimide compound is a compound having a structural unit represented by the following formula (2). In the following formula (2), each of the right end portion and the left end portion is a binding site with another group. Only one type of the carbodiimide compound may be used, or two or more types thereof may be used in combination.

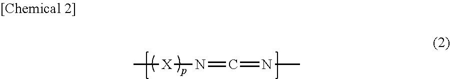

In the formula (2), X represents an alkylene group, a group in which a substituent is bonded to an alkylene group, a cycloalkylene group, a group in which a substituent is bonded to a cycloalkylene group, an arylene group, or a group in which a substituent is bonded to an arylene group, and p represents an integer of 1 to 5. When there are a plurality of Xs, the plurality of Xs may be the same or different.

In a preferred embodiment, at least one X is an alkylene group, a group in which a substituent is bonded to an alkylene group, a cycloalkylene group, or a group in which a substituent is bonded to a cycloalkylene group.

Examples of commercially available products of the carbodiimide compound include “CARBODILITE V-02B”, “CARBODILITE V-03”, “CARBODILITE V-04K”, “CARBODILITE V-07”, “CARBODILITE V-09”, “CARBODILITE 10M-SP”, and “CARBODILITE 10M-SP (modified)” manufactured by Niisshinbo Chemical Inc., and “Stabaxol P”, “Stabaxol P400”, and “HIKAZIL 510” manufactured by Rhein Chemie Rheinau GmbH.

<Acid Anhydride>

Examples of the acid anhydride include tetrahydrophthalic anhydride and an alkylstyrene-maleic anhydride copolymer.

Examples of commercially available products of the acid anhydride include “RIKACID TDA-100” manufactured by New Japan Chemical Co., Ltd.

The content of the curing agent is preferably 70 parts by weight or more, and more preferably 85 parts by weight or more, but preferably 150 parts by weight or less, and more preferably 120 parts by weight or less, based on 100 parts by weight of the first thermosetting compound. When the content of the curing agent is the above lower limit or more and the above upper limit or less, the curability is further excellent, the thermal dimensional stability is further enhanced, and volatilization of remaining unreacted components can be further suppressed.

The content of the curing agent is preferably 70 parts by weight or more, and more preferably 85 parts by weight or more, but preferably 150 parts by weight or less, and more preferably 120 parts by weight or less, based on total 100 parts by weight of the first thermosetting compound and the thermosetting compound excluding the curing agent in the second thermosetting compound. When the content of the curing agent is the above lower limit or more and the above upper limit or less, the curability is further excellent, the thermal dimensional stability is further enhanced, and volatilization of remaining unreacted components can be further suppressed.

The total content of the first thermosetting compound and the curing agent is preferably 50 wt % or more, and more preferably 60 wt % or more, but preferably 95 wt % or less in 100 wt % of components excluding an inorganic filler and a solvent in the resin material. When the total content of the first thermosetting compound and the curing agent is the above lower limit or more and the above upper limit or less, the curability is further excellent, and the thermal dimensional stability can be further enhanced.

The total content of the first thermosetting compound and the second thermosetting compound is preferably 50 wt % or more, and more preferably 60 wt % or more, but preferably 95 wt % or less in 100 wt % of components excluding an inorganic filler and a solvent in the resin material. When the total content of the first thermosetting compound and the second thermosetting compound is the above lower limit or more and the above upper limit or less, the curability is further excellent, and the thermal dimensional stability can be further enhanced.

### [Inorganic Filler]

The resin material contains an inorganic filler. By using the inorganic filler, the dielectric loss tangent of the cured product can be further lowered. In addition, by using the inorganic filler, the dimensional change of the cured product due to heat is further reduced. Only one type of the inorganic filler may be used, or two or more types thereof may be used in combination.

Examples of the inorganic filler include silica, talc, clay, mica, hydrotalcite, alumina, magnesium oxide, aluminum hydroxide, aluminum nitride, and boron nitride.

From the viewpoint of reducing the surface roughness of the surface of the cured product, further increasing the adhesive strength between the cured product and the metal layer, forming finer wiring on the surface of the cured product, and imparting better insulation reliability to the cured product, the inorganic filler is preferably silica or alumina, more preferably silica, and further preferably fused silica. By using silica, the thermal expansion coefficient of the cured product is further lowered, and the dielectric loss tangent of the cured product is further lowered. In addition, by using silica, the surface roughness of the surface of the cured product is effectively reduced, and the adhesive strength between the cured product and the metal layer is effectively increased. The shape of silica is preferably spherical.

The inorganic filler is preferably spherical silica from the viewpoint of promoting curing of the resin regardless of the curing environment, effectively increasing the glass transition temperature of the cured product, and effectively decreasing the thermal linear expansion coefficient of the cured product.

The average particle diameter of the inorganic filler is preferably 50 nm or more, more preferably 100 nm or more, and further preferably 500 nm or more, but preferably 5 μm or less, more preferably 3 μm or less, and further preferably 1 μm or less. When the average particle diameter of the inorganic filler is the above lower limit or more and the above upper limit or less, the degree of surface roughness after etching can be reduced, the plating peel strength can be increased, and the adhesion between the insulating layer and the metal layer can be further enhanced.

As the average particle diameter of the inorganic filler, a value of a median diameter (d50) corresponding to a particle diameter at which the volumetric integrated value becomes 50% in the particle size distribution is employed. The average particle diameter can be measured using a laser diffraction scattering type particle size distribution measuring apparatus.

The inorganic filler is preferably spherical, and more preferably spherical silica. In this case, the surface roughness of the surface of the cured product is effectively reduced, and the adhesive strength between the cured product and the metal layer is effectively increased. When the inorganic filler is spherical, the aspect ratio of the inorganic filler is preferably 2 or less, and more preferably 1.5 or less.

The inorganic filler is preferably surface-treated, more preferably surface-treated with a coupling agent, and further preferably surface-treated with a silane coupling agent. When the inorganic filler is surface-treated, the surface roughness of the surface of the roughened cured product is further reduced, and the adhesive strength between the cured product and the metal layer is further increased. In addition, since the inorganic filler is surface-treated, finer wiring can be formed on the surface of the cured product, and further better inter-wiring insulation reliability and interlayer insulation reliability can be imparted to the cured product.

Examples of the coupling agent include a silane coupling agent, a titanium coupling agent, and an aluminum coupling agent. Examples of the silane coupling agent include methacrylsilane, acrylsilane, aminosilane, imidazolesilane, vinylsilane, and epoxysilane.

In the present invention, the content of the inorganic filler is 30 wt % or more in 100 wt % of components excluding a solvent in the resin material. In the present invention, even when the content of the inorganic filler is 30 wt % or more, the effect of the present invention can be exhibited.

The content of the inorganic filler is preferably 40 wt % or more, and further preferably 50 wt % or more, but preferably 90 wt or less, more preferably 85 wt % or less, and further preferably 80 wt % or less in 100 wt % of components excluding a solvent in the resin material. When the content of the inorganic filler is the above lower limit or more, the dielectric loss tangent is effectively lowered. When the content of the inorganic filler is the above upper limit or less, the thermal dimensional stability can be enhanced, and warpage of the cured product can be effectively suppressed. When the content of the inorganic filler is the above lower limit or more and the above upper limit or less, the surface roughness of the surface of the cured product can be further reduced, and finer wiring can be formed on the surface of the cured product. Furthermore, with the content of the inorganic filler, the thermal expansion coefficient of the cured product can be lowered, and at the same time, the smear removability can be improved.

### [Curing Accelerator]

The resin material preferably contains a curing accelerator. By using the curing accelerator, the curing rate is further increased. By rapidly curing the resin material, the crosslinked structure in the cured product becomes uniform, the number of unreacted functional groups decreases, and as a result, the crosslinking density increases. The curing accelerator is not particularly limited, and a conventionally known curing accelerator can be used. One type of the curing accelerator may be used alone, and two or more types thereof may be used in combination.

Examples of the curing accelerator include anionic curing accelerators such as imidazole compounds, cationic curing accelerators such as amine compounds, curing accelerators other than anionic and cationic curing accelerators, such as phosphorus compounds and organometallic compounds, and radical curing accelerators such as peroxides.

Examples of the imidazole compound include 2-undecylimidazole, 2-heptadecylimidazol, 2-methylimidazole, 2-ethyl-4-methylimidazole, 2-phenylimidazole, 2-phenyl-4-methylimidazole, 1-benzyl-2-methylimidazole, 1-benzyl-2-phenylimidazole, 1,2-dimethylimidazole, 1-cyanoethyl-2-methylimidazole, 1-cyanoethyl-2-ethyl-4-methylimidazole, 1-cyanoethyl-2-undecylimidazole, 1-cyanoethyl-2-phenylimidazole, 1-cyanoethyl-2-undecylimidazolium trimellitate, 1-cyanoethyl-2-phenylimidazolium trimellitate, 2,4-diamino-6-[2′-methylimidazolyl-(1′)]-ethyl-s-triazine, 2,4-diamino-6-[2′-undecylimidazolyl-(1′)]-ethyl-s-triazine, 2,4-diamino-6-[2′-ethyl-4′-methylimidazolyl-(1′)]-ethyl-s-triazine, 2,4-diamino-6-[2′-methylimidazolyl-(1′)]-ethyl-s-triazine isocyanuric acid adduct, 2-phenylimidazole isocyanuric acid adduct, 2-methylimidazole isocyanuric acid adduct, 2-phenyl-4,5-dihydroxymethylimidazole, and 2-phenyl-4-methyl-5-dihydroxymethylimidazole.

Examples of the amine compound include diethylamine, triethylamine, diethylenetetramire, triethylenetetramine, and 4,4-dimethylaminopyridine.

Examples of the phosphorus compound include triphenylphosphinine compounds.

Examples of the organometallic compound include zinc naphthenate, cobalt naphthenate, tin octylate, cobalt octylate, bisacetylacetonate cobalt (II), and trisacetylacetonate cobalt (III).

Examples of the peroxide include dicumyl peroxide and perhexyl 25B.

From the viewpoint of further suppressing the curing temperature to a lower level and effectively suppressing warpage of the cured product, the curing accelerator preferably contains the anionic curing accelerator, and more preferably contains the imidazole compound.

From the viewpoint of further suppressing the curing temperature to a lower level and effectively suppressing warpage of the cured product, the content of the anionic curing accelerator is preferably 20 wt % or more, more preferably 50 wt % or more, further preferably 70 wt % or more, and most preferably 100 wt % (total amount) in 100 wt % of the curing accelerator. Therefore, the curing accelerator is most preferably the anionic curing accelerator.

The content of the curing accelerator is not particularly limited. The content of the curing accelerator is preferably 0.01 wt % or more, and more preferably 0.05 wt % or more, but preferably 5 wt % or less, and more preferably 3 wt % or less in 100 wt % of components excluding an inorganic filler and a solvent in the resin material. When the content of the curing accelerator is the above lower limit or more and the above upper limit or less, the resin material is efficiently cured. When the content of the curing accelerator is in a more preferable range, the storage stability of the resin material is further enhanced, and a further favorable cured product can be obtained.

### [Thermoplastic Resin]

The resin material preferably contains a thermoplastic resin. Examples of the thermoplastic resin include polyvinyl acetal resins, polyimide resins, and phenoxy resins. Only one type of the thermoplastic resin may be used, or two or more types thereof may be used in combination.

The thermoplastic resin is preferably a phenoxy resin from the viewpoint of effectively reducing the dielectric loss tangent and effectively enhancing adhesion of metal wiring regardless of the curing environment. By using the phenoxy resin, deterioration of the embeddability of the resin film in the holes or irregularities of the circuit board and nonuniformity of the inorganic filler can be suppressed. In addition, since the melt viscosity can be adjusted by using the phenoxy resin, the dispersibility of the inorganic filler is improved, and the resin composition or the B-stage product is less likely to wet and spread in an unintended region in the curing process.

The phenoxy resin contained in the resin material is not particularly limited. As the phenoxy resin, a conventionally known phenoxy resin can be used. Only one type of the phenoxy resin may be used, or two or more types thereof may be used in combination.

Examples of the phenoxy resin include phenoxy resins having a backbone such as a bisphenol A type backbone, a bisphenol F type backbone, a bisphenol S type backbone, a biphenyl backbone, a novolac backbone, a naphthalene backbone, and an imide backbone.

Examples of commercially available products of the phenoxy resin include “YP50”, “YP55”, and “YP70” manufactured by Nippon Steel & Sumikin Chemical Co., Ltd., and “1256B40”, “4250”, “4256H40”, “4275”, “YX6954BH30”, and “YX8100BH30” manufactured by Mitsubishi Chemical Corporation.

From the viewpoint of enhancing the handleability, the plating peel strength at a low degree of roughness, and the adhesion between the insulating layer and the metal layer, the thermoplastic resin is preferably a polyimide resin (polyimide compound).

From the viewpoint of improving the solubility, further lowering the dielectric loss tangent, and further shortening the baking time, the polyimide compound is preferably a polyimide compound obtained by a method of reacting a tetracarboxylic dianhydride with a dimer diamine.

Examples of the tetracarboxylic dianhydride include pyromellitic dianhydride, 3,3′,4,4′-benzophenornetetracarboxylic dianhydride, 3,3′,4,4′-biphenylsulfonetetracarboxylic dianhydride, 1,4,5,8-naphthalenetetracarboxylic dianhydride, 2,3,6,7-riaphthalenetetracarboxylic dianhydride, 3,3′,4,4′-biphenyl ether tetracarboxylic dianhydride, 3,3′,4,4′-dimethyldiphenylsilane tetracarboxylic dianhydride, 3,3′,4,4′-tetraphenylsilane tetracarboxylic dianhydride, 1,2,3,4-furantetracarboxylic dianhydride, 4,4′-bis(3,4-dicarboxyphenoxy)diphenyl disulfide dianhydride, 4,4′-bis(3,4-dicarboxyphenoxy)diphenylsulfone dianhydride, 4,4′-bis(3,4-dicarboxyphenoxy)diphenylpropane dianhydride, 3,3′,4,4′-perfluoroisopropylidenediphthalic acid dianhydride, 3,3′,4,4′-biphenyltetracarboxylic acid dianhydride, bis(phthalic acid)phenylphosphine oxide dianhydride, p-phenylene-bis(triphenylphthalic acid)dianhydride, m-phenylene-bis(triphenylphthalic acid)dianhydride, bis(triphenylphthalic acid)-4,4′-diphenylether dianhydride, and bis(triphenylphthalic acid)-4,4′-diphenylmethane dianhydride.

Examples of the dimer diamine include Versamine 551 (trade name, 3,4-bis(1-aminoheptyl)-6-hexyl-5-(1-octenyl)cyclohexene, manufactured by BASF Japan Ltd.), Versamine 552 (trade name, a hydrogenated product of Versamine 551, manufactured by Cognis Japan Ltd.), PRIAMINE 1075, and PRIAMINE 1074 (trade name, both manufactured by Croda Japan KK).

The polyimide compound may have an acid anhydride structure, a maleimide structure, or a citraconimide structure at the terminal. In this case, the polyimide compound and the epoxy resin can be reacted. The thermal dimensional stability of the cured product can be enhanced by reacting the polyimide compound with the epoxy resin.

From the viewpoint of obtaining a resin material further excellent in storage stability, the weight average molecular weights of the thermoplastic resin, the polyimide resin, and the phenoxy resin are preferably 3,000 or more, more preferably 5,000 or more, and further preferably 10,000 or more, but preferably 100,000 or less, and more preferably 50,000 or less.

The weight average molecular weights of the thermoplastic resin, the polyimide resin, and the phenoxy resin refer to a weight average molecular weight in terms of polystyrene measured by gel permeation chromatography (GPC).

The contents of the thermoplastic resin, the polyimide resin, and the phenoxy resin are not particularly limited. The content (when the thermoplastic resin is a polyimide resin or a phenoxy resin, the content of the polyimide resin or the phenoxy resin) of the thermoplastic resin is preferably 1 wt % or more, and more preferably 2 wt % or more, but preferably 30 wt % or less, and more preferably 20 wt % or less in 100 wt % of components excluding the inorganic filler and the solvent in the resin material. When the content of the thermoplastic resin is the above lower limit or more and the above upper limit or less, the embeddability of the resin material into the holes or irregularities of the circuit board are improved. When the content of the thermoplastic resin is the above lower limit or more, formation of the resin film is further facilitated, and a better insulating layer is obtained. When the content of the thermoplastic resin is the above upper limit or less, the thermal expansion coefficient of the cured product is further lowered. When the content of the thermoplastic resin is the above upper limit or less, the surface roughness of the surface of the cured product is further reduced, and the adhesive strength between the cured product and the metal layer is further increased.

### [Solvent]

The resin material does not contain or contains a solvent. By using the solvent, the viscosity of the resin material can be controlled within a suitable range, and the coatability of the resin material can be enhanced. The solvent may be used for obtaining a slurry containing the inorganic filler. Only one type of the solvent may be used, or two or more types thereof may be used in combination.

Examples of the solvent include acetone, methanol, ethanol, butanol, 2-propanol, 2-methoxyethanol, 2-ethoxyethanol, 1-methoxy-2-propanol, 2-acetoxy-1-methoxypropane, toluene, xylene, methyl ethyl ketone, N,N-dimethylformamide, methyl isobutyl ketone, N-methyl-pyrrolidone, n-hexane, cyclohexane, cyclohexanone, and naphtha which is a mixture.

Most of the solvent is preferably removed when the resin composition is formed into a film. Therefore, the boiling point of the solvent is preferably 200° C. or less, and more preferably 180° C. or less. The content of the solvent in the resin composition is not particularly limited. The content of the solvent can be appropriately changed in consideration of, for example, the coatability of the resin composition.

When the resin material is a B-stage film, the content of the solvent is preferably 1 wt % or more, and more preferably 2 wt % or more, but preferably 10 wt % or less, and more preferably 5 wt % or less in 100 wt % of the B-stage film.

### [Other Components]

For the purpose of improving the impact resistance, heat resistance, resin compatibility, workability, and the like, the resin material may contain a leveling agent, a flame retardant, a coupling agent, a colorant, an antioxidant, an ultraviolet degradation inhibitor, an antifoaming agent, a thickener, a thixotropy imparting agent, for example.

Examples of the coupling agent include a silane coupling agent, a titanium coupling agent, and an aluminum coupling agent. Examples of the silane coupling agent include vinylsilane, aminosilane, imidazolesilane, and epoxysilane.

### (Resin Film)

A resin film (B-stage product/B-stage film) is obtained by forming the above-described resin composition into a film. The resin material is preferably a resin film. The resin film is preferably a B-stage film.

Examples of a method for forming a resin composition into a film to obtain a resin film includes the following methods: an extrusion molding method of melt-kneading a resin composition using an extruder, extruding the melt-kneaded resin composition, and then forming the melt-kneaded resin composition into a film using a T-die, a circular die, or the like; a casting molding method of casting a resin composition containing a solvent to form the resin composition into a film; and other conventionally known film forming methods. An extrusion molding method or a casting molding method is preferable because it can cope with a reduction in thickness. The film includes a sheet.

A resin film as a B-stage film can be obtained by forming a resin composition into a film, and heating and drying the resin composition at, for example, 50° C. to 150° C. for 1 minute to 10 minutes to such an extent that curing by heat does not excessively proceed.

The film-shaped resin composition that can be obtained by the drying process as described above is referred to as a B-stage film. The B-stage film is in a semi-cured state. The semi-cured product is not completely cured, and curing may further proceed.

The resin film is not required to be a prepreg. When the resin film is not a prepreg, migration does not occur along the glass cloth or the like. Further, when the resin film is laminated or pre-cured, irregularities caused by the glass cloth are not generated on the surface.

The resin film can be used in the form of a laminated film including a metal foil or a substrate film, and a resin film laminated on the surface of the metal foil or the substrate film. The metal foil is preferably a copper foil.

Examples of the substrate film of the laminated film include polyester resin films such as polyethylene terephthalate films and polybutylene terephthalate films, olefin resin films such as polyethylene films and polypropylene films, and polyimide resin films. The surface of the substrate film may be subjected to a release treatment as necessary.

From the viewpoint of controlling the degree of curing of the resin film more uniformly, the thickness of the resin film is preferably 5 μm or more, and preferably 200 μm or less. When the resin film is used as an insulating layer of a circuit, the thickness of the insulating layer formed of the resin film is preferably equal to or more than the thickness of a conductor layer (metal layer) forming the circuit. The thickness of the insulating layer is preferably 5 μm or more, and preferably 200 μm or less.

### (Semiconductor Device, Printed Wiring Board, Copper-Clad Laminated Plate, and Multilayer Printed Wiring Board)

The resin material is suitably used for forming a mold resin for embedding a semiconductor chip in a semiconductor device.

The resin material is suitably used as an insulating material. The resin material is suitably used for forming an insulating layer in a printed wiring board.

The printed wiring board is obtained, for example, by molding the resin material through application of heat and pressure.

A lamination target member having a metal layer on one surface or both surfaces thereof can be laminated on the resin film. A laminated structure including a lamination target member having a metal layer on a surface thereof and a resin film laminated on a surface of the metal layer, in which the resin film is the resin material described above, can be suitably obtained. The method for laminating the resin film and the lamination target member having a metal layer on the surface thereof is not particularly limited, and a known method can be used. For example, using a device such as a parallel plate pressing machine or a roll laminator, the resin film can be laminated on the lamination target member having a metal layer on the surface thereof while heating or pressurizing without heating.

The material of the metal layer is preferably copper.

The lamination target member having a metal layer on the surface thereof may be a metal foil such as a copper foil.

The resin material is suitably used for obtaining a copper-clad laminated plate. An example of the copper-clad laminated plate includes a copper-clad laminated plate including a copper foil and a resin film laminated on one surface of the copper foil.

The thickness of the copper foil of the copper-clad laminated plate is not particularly limited. The thickness of the copper foil is preferably in a range of 1 μm to 50 μm. In addition, in order to increase the adhesive strength between the cured product of the resin material and the copper foil, the copper foil preferably has fine irregularities on the surface thereof. The method for forming the irregularities is not particularly limited. Examples of the method for forming the irregularities include a forming method by a treatment using a known chemical solution.

The resin material is suitably used for obtaining a multilayer substrate.

An example of the multilayer substrate includes a multilayer substrate including a circuit board and an insulating layer laminated on the circuit board. The insulating layer of the multilayer substrate is formed of the resin material. The insulating layer of the multilayer substrate may be formed of the resin film of a laminated film by using the laminated film. The insulating layer is preferably laminated on the surface of the circuit board on which the circuit is provided. A part of the insulating layer is preferably embedded between the circuits.

In the multilayer substrate, a surface of the insulating layer on a side opposite to a surface on which the circuit board is laminated is preferably subjected to a roughening treatment.

As the roughening treatment method, a conventionally known roughening treatment method can be used, and the method is not particularly limited thereto. The surface of the insulating layer may be subjected to a swelling treatment before the roughening treatment.

The multilayer substrate preferably further includes a copper plating layer laminated on the roughened surface of the insulating layer.

Another example of the multilayer substrate includes a multilayer substrate including a circuit board, an insulating layer laminated on a surface of the circuit board, and a copper foil laminated on a surface of the insulating layer on a side opposite to a surface on which the circuit board is laminated. The insulating layer is preferably formed by curing the resin film using a copper-clad laminated plate including a copper foil and a resin film laminated on one surface of the copper foil. Further, the copper foil is etched, and is preferably a copper circuit.

Another example of the multilayer substrate includes a multilayer substrate including a circuit board and a plurality of insulating layers laminated on a surface of the circuit board. At least one of the plurality of insulating layers disposed on the circuit board is formed using the resin material. The multilayer substrate preferably further includes a circuit laminated on at least one surface of the insulating layer formed using the resin film.

In a multilayer printed wiring board among multilayer substrates, low dielectric loss tangent is required, and high insulation reliability provided by the insulating layer is required. In the resin material according to the present invention, the insulation reliability can be effectively enhanced by lowering the dielectric loss tangent and exhibiting the effect of the present invention. Accordingly, the resin material according to the present invention is suitably used for forming the insulating layer in the multilayer printed wiring board.

The multilayer printed wiring board includes, for example, a circuit board, a plurality of insulating layers disposed on a surface of the circuit board, and a metal layer disposed between the plurality of insulating layers. At least one of the insulating layers is a cured product of the resin material.

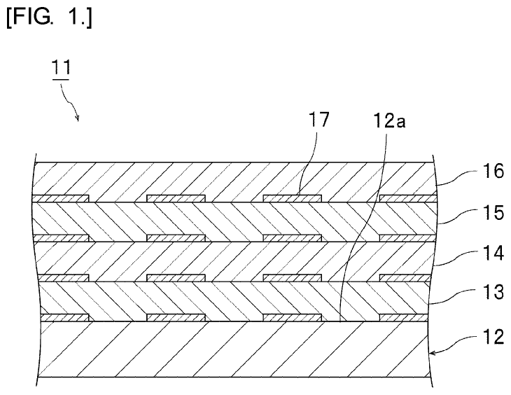

FIG. 1 is a cross-sectional view schematically illustrating a multilayer printed wiring board using a resin material according to an embodiment of the present invention.

In a multilayer printed wiring board 11 shown in FIG. 1, a plurality of insulating layers 13 to 16 are laminated on an upper surface 12a of a circuit board 12. The insulating layers 13 to 16 are a cured product layer. The metal layers 17 are formed in a partial region of the upper surface 12a of the circuit board 12. The metal layers 17 are formed in a partial region of the upper surfaces of the insulating layers 13 to 15 other than the insulating layer 16 located on the outer surface opposite to the circuit board 12 side among the plurality of insulating layers 13 to 16. The metal layers 17 are a circuit. The metal layers 17 are disposed between the circuit board 12 and the insulating layer 13, and between laminated individual insulating layers 13 to 16. The lower metal layer 17 and the upper metal layer 17 are connected to each other by at least one of via hole connection and through hole connection (not illustrated)).

In the multilayer printed wiring board 11, the insulating layers 13 to 16 are formed of a cured product of the resin material. In the present embodiment, since the surfaces of the insulating layers 13 to 16 are subjected to a roughening treatment, fine pores (not illustrated) are formed on the surfaces of the insulating layers 13 to 16. In addition, the metal layer 17 reaches the inside of the fine pore. In the multilayer printed wiring board 11, dimension (L) in the width direction of metal layer 17 and dimension (S) in the width direction of the portion where the metal layer 17 is not formed can be reduced. In the multilayer printed wiring board 11, good insulation reliability is imparted between the upper metal layer and the lower metal layer which are not connected by via hole connection and through hole connection (not illustrated).

### (Roughening Treatment and Swelling Treatment)

The resin material is preferably used for obtaining a cured product to be subjected to a roughening treatment or a desmear treatment. The cured product also includes a precured product that can be further cured.

The cured product is preferably subjected to a roughening treatment in order to form fine irregularities or the surface of the cured product obtained by pre-curing the resin material. The cured product is preferably subjected to a swelling treatment before the roughening treatment. The cured product is preferably subjected to a swelling treatment after pre-curing and before being subjected to a roughening treatment, and further cured after the roughening treatment. However, the cured product is not necessarily subjected to a swelling treatment.

As a method of performing the swelling treatment, for example, a method of treating a cured product with an aqueous solution or an organic solvent dispersion solution of a compound containing ethylene glycol or the like as a main component is used. The swelling liquid used for the swelling treatment generally contains an alkali as a pH adjusting agent or the like. The swelling liquid preferably contains sodium hydroxide. Specifically, for example, the swelling treatment is performed by treating a cured product at a treatment temperature of 30° C. to 85° C. for 1 minute to 30 minutes using a 40 wt % aqueous ethylene glycol solution or the like. The temperature of the swelling treatment is preferably in a range of 50° C. to 85° C. When the temperature of the swelling treatment is too low, a long time is required for the swelling treatment, and the adhesive strength between the cured product and the metal layer tends to decrease.

In the roughening treatment, for example, a chemical oxidizing agent such as a manganese compound, a chromium compound, or a persulfuric acid compound is used. These chemical oxidizing agents are used as an aqueous solution or an organic solvent dispersion solution after water or an organic solvent is added. The roughening liquid used for the roughening treatment generally contains an alkali as a pH adjusting agent or the like. The roughening liquid preferably contains sodium hydroxide.

Examples of the manganese compound include potassium permanganate and sodium permanganate. Examples of the chromium compound include potassium dichromate and anhydrous potassium chromate. Examples of the persulfuric acid compound include sodium persulfate, potassium persulfate, and ammonium persulfate.

The arithmetic average roughness Ra of the surface of the cured product is preferably 10 nm or more, preferably less than 300 nm, more preferably less than 200 nm, and further preferably less than 150 nm. In this case, the adhesive strength between the cured product and the metal layer is increased, and finer wiring is formed on the surface of the insulating layer. Furthermore, the conductor loss can be suppressed, and the signal loss can be suppressed low. The arithmetic average roughness Ra is measured in accordance with JIS B0601:1994.

### (Desmear Treatment)

A penetration hole may be formed in a cured product obtained by pre-curing the resin material. In the multilayer substrate or the like, a via hole, a through hole, or the like is formed as the penetration hole. For example, the via hole can be formed by irradiation with a laser such as a CO, laser. The diameter of the via hole is not particularly limited, but is approximately 60 μm to 80 μm. Due to the formation of the penetration hole, smears, which are residues of the resin derived from a resin component contained in the cured product, are often formed at the bottom portion in the via hole.

In order to remove the smears, the surface of the cured product is preferably subjected to a desmear treatment. The desmear treatment may also serve as a roughening treatment.

In the desmear treatment, as in the roughening treatment, for example, a chemical oxidizing agent such as a manganese compound, a chromium compound, or a persulfuric acid compound is used. These chemical oxidizing agents are used as an aqueous solution or an organic solvent dispersion solution after water or an organic solvent is added. The desmear treatment liquid used for the desmear treatment generally contains an alkali. The desmear treatment liquid preferably contains sodium hydroxide.

By using the resin material, the surface roughness of the surface of the cured product subjected to the desmear treatment is sufficiently reduced.

Hereinafter, the present invention will be specifically described with reference to Examples and Comparative Examples. The present invention is not limited to the following Examples.

The following materials were prepared.

### (First Thermosetting Compound)

Thermosetting Compound X1:

A higher fatty acid, “FINEOXOCOL ISOSTEARIC ACID” manufactured by Nissan Chemical Corporation was prepared.

In a reaction flask, 50 parts by weight of FINEOXOCOL ISOSTEARIC ACID, 40 parts by weight of allyl bromide, 19 parts by weight of potassium carbonate, and 450 parts by weight of N-methyl-2-pyrrolidone were placed, and the mixture was reacted under stirring at 70° C. for 3 hours. The obtained reaction solution was filtered, and the filtrate was washed with toluene and water, and the organic layer was extracted, then the solvent was distilled off. The obtained residue was purified by silica gel chromatography. In a reaction flask, 50 parts by weight of the compound obtained by purification and 660 parts by weight of chloroform were placed. To the obtained solution, 80 parts by weight of 3-chloroperoxybenzoic acid (purity: 70%) was added with stirring, and the mixture was reacted under stirring at room temperature for 6 days. To the obtained reaction solution, 450 parts by weight of a 10 mass, aqueous sodium thiosulfate solution was added. The organic layer was washed with a 5 mass % aqueous sodium bicarbonate solution and water, and then the solvent was distilled off. The obtained residue was purified by silica gel chromatography to obtain thermosetting compound X1 as a glycidyl ester compound.

Thermosetting Compound X2:

A higher fatty acid, “FINEOXOCOL ISOSTEARIC ACID N” manufactured by Nissan Chemical Corporation was prepared. Except that FINEOXOCOL ISOSTEARIC ACID N was used in place of FINEOXOCOL ISOSTEARIC ACID, the same procedure as in the method for synthesizing thermosetting compound X1 was carried out to obtain thermosetting compound X2 as a glycidyl ester compound.

Thermosetting Compound X3:

In a reaction flask, 30 parts by weight of 3,5,5-trimerylhexyl alcohol, 45 parts by weight of allyl bromide, 20 parts by weight of sodium hydride, and 500 parts by weight of tetrahydrofuran were placed, and the mixture was reacted under stirring at 70° C. for 30 hours. The obtained reaction solution was washed with water and extracted, and then the solvent was distilled off. The obtained residue was purified by silica gel chromatography. In a reaction flask, 30 parts by weight of the compound obtained by purification and 400 parts by weight of chloroform were placed. To the obtained solution, 50 parts by weight of 3-chloroperoxybenzoic acid was added with stirring, and the mixture was reacted under stirring at room temperature for 4 days. To the obtained reaction solution, 300 parts by weight of a 10 mass % aqueous sodium thiosulfate solution was added. The organic layer was washed with a 5 mass aqueous sodium bicarbonate solution and water, and then the solvent was distilled off. The obtained residue was purified by silica gel chromatography to obtain thermosetting compound X3 as a glycidyl ether compound.

Thermosetting Compound X4:

A higher fatty acid, “FINEOXOCOL ISOSTEARIC ACID T” manufactured by Nissan Chemical Corporation was prepared. Except that FINEOXOCOL ISOSTEARIC ACID T was used in place of FINEOXOCOL ISOSTEARIC ACID, the same procedure as in the method for synthesizing thermosetting compound X1 was carried out to obtain thermosetting compound X4 as a glycidyl ester compound.

Thermosetting Compound X5:

An epoxy compound (glycidyl ether compound), “FOLDI E201” manufactured by Nissan Chemical Corporation was used as thermosetting compound X5.

Thermosetting Compound X6:

An epoxy compound (2-ethylhexyl glycidyl ether), “EX-121” manufactured by Nagase ChemteX Corporation was used as thermosetting compound X6.

Thermosetting Compound X7:

In a reaction vessel equipped with a dropping funnel, a stirrer, a thermometer, a nitrogen inlet tube, and an aqueous sodium hydroxide solution trap, 20 parts by weight of maleimide acetic acid and 200 parts by weight of toluene were placed, and 50 parts by weight of thionyl chloride was added dropwise with stirring at room temperature. After completion of the dropwise addition, the reaction mixture was heated at 50° C. for 5 hours with stirring. The reaction mixture was distilled off under reduced pressure to obtain maleimide acetic acid chloride. In a reaction vessel, 30 parts by weight of maleimide acetic acid chloride, 42 parts by weight of FINEOXOCOL 180 (manufactured by Nissan Chemical Corporation), 0.2 parts by weight of p-methoxyphenol, and 450 parts by weight of toluene were placed, and the mixture was stirred for 2 hours while being heated to 100° C. To the resulting solution, 10 parts by weight of pyridine was added dropwise over 30 minutes, and the mixture was stirred for 2 hours. Toluene was distilled off from the reaction mixture under reduced pressure, and the residue was dissolved in an ethyl acetate/toluene mixed solvent and recrystallized. Then, the solvent was removed to obtain thermosetting compound X7 as a maleimide compound.

### (Second Thermosetting Compound)

Thermosetting Compound Y1:

Except that 3,5-di-tertiary-butylbenzyl alcohol was used in place of 3,5,5-trimerylhexyl alcohol, the same procedure as in the method for synthesizing thermosetting compound X3 was carried out to obtain thermosetting compound Y1 as a glycidyl ether compound.

Thermosetting Compound Y2:

An epoxy compound, “YX8034” manufactured by Mitsubishi Chemical Corporation was used as thermosetting compound Y2.

Thermosetting Compound Y3:

An epoxy compound, “JER871” manufactured by Mitsubishi Chemical Corporation was used as thermosetting compound Y3.

Thermosetting Compound Y4:

A biphenyl type epoxy compound, “NC-3000” manufactured by Nippon Kayaku Co., Ltd. was used as thermosetting compound Y4.

Thermosetting Compound Y5:

An epoxy compound, “OGSGL PG-100” manufactured by Osaka Gas Chemicals Co., Ltd. was used as thermosetting compound Y5.

Thermosetting Compound Y6:

An active ester compound, “HPC-8900-70BK” (active ester compound-containing liquid, solid content: 70 wt %) manufactured by DIC Corporation was used as a liquid containing thermosetting compound Y6.

Thermosetting Compound Y7:

A phenol compound-containing liquid, “LA-1356” (phenol compound-containing liquid, solid content: 60 wt %) manufactured by DIC Corporation was used as a liquid containing thermosetting compound Y7.

Thermosetting Compound Y8:

An active ester compound, “HPC-8150-62T” (active ester compound-containing liquid, solid content: 62 wt %) manufactured by DIC Corporation was used as a liquid containing thermosetting compound Y8.

Thermosetting Compound Y9:

Under a nitrogen stream, 14.4 g of 1-naphthol, 350 g of tetrahydrofuran (THF), and 12.1 g of triethylamine were placed in a three-necked flask, and the mixture was stirred until it became uniform. Then, 9.1 g of isophthaloyl chloride was slowly added dropwise to the mixture while the three-necked flask was cooled under an ice bath. After the dropwise addition, the mixture was stirred at normal temperature (23° C.) for 1 hour to allow the reaction to proceed. After the reaction, ethyl acetate was added to the reaction solution, and the solution was washed with a 1 mol/L aqueous nitric acid solution and then further washed with water. The organic layer after washing was dried using anhydrous magnesium sulfate, and the solution was distilled off under reduced pressure to obtain thermosetting compound Y9 as an active ester compound.

Thermosetting Compound Y10:

Using a vessel equipped with a stirrer, a reflux condenser, and a Dean-Stark water separator, 21.1 parts by weight of trimellitic anhydride chloride was dissolved in 200 parts by weight of N-methyl-2-pyrrolidone. To the obtained solution, 14.4 parts by weight of 2-naphthol was added, 10.1 parts by weight of triethylamine was further added, and the mixture was reacted under stirring at 25° C. for 4 hours. To the obtained reaction solution, 8.9 parts by weight of a mixture of 2-methyl-4,6-diethyl-1,3-phenylenediamine and 2,4-diethyl-6-methyl-1,3-phenylenediamine was added, and the mixture was reacted under stirring at 25° C. for 4 hours. To the obtained solution, 200 parts by weight of toluene was added, and then the solution was refluxed at 150° C. for 4 hours until no water was generated. After completion of the reaction, a solution obtained by removing toluene from the obtained solution using an evaporator was added dropwise to 800 parts by weight of pure water. A precipitate was separated by filtration and then vacuum-dried to obtain thermosetting compound Y10 as an active ester compound.

Thermosetting Compound Y11:

Using a vessel equipped with a stirrer, a reflux condenser, and a Dean-Stark water separator, 21.1 parts by weight of trimellitic anhydride chloride was dissolved in 200 parts by weight of N-methyl-2-pyrrolidone. To the obtained solution, 14.4 parts by weight of 2-naphthol was added, 10.1 parts by weight of triethylamine was further added, and the mixture was reacted under stirring at 25° C. for 4 hours. To the obtained reaction solution, 14.6 parts by weight of 1,3-bis(3-aminophenoxy)benzene was added, and the mixture was reacted under stirring at 25° C. for 4 hours. To the obtained solution, 200 parts by weight of toluene was added, and then the solution was refluxed at 150° C. for 4 hours until no water was generated. After completion of the reaction, a solution obtained by removing toluene from the obtained solution using an evaporator was added dropwise to 800 parts by weight of pure water. A precipitate was separated by filtration and then vacuum-dried to obtain thermosetting compound Y11 as an active ester compound. The equivalent weight of thermosetting compound Y11 was 446.

The details of thermosetting compounds X1 to X7 and Y1 to Y3 are shown in Tables 1 and 2 below.

TABLE 1

| | | | | | | | |
|---|---|---|---|---|---|---|---|
| Type of thermosetting | ×1 | ×2 | ×3 | ×4 | ×5 | ×6 | ×7 |
| compound | | | | | | | |
| Presence of aromatic ring | No | No | No | No | No | No | No |
| in structural portion excluding | | | | | | | |
| thermosetting funtional group | | | | | | | |
| Presence of branched structure | Yes | Yes | Yes | Yes | Yes | Yes | Yes |
| in structural portion excluding | | | | | | | |
| thermosetting functional group | | | | | | | |
| Number of CH2 terminals in | 8 | 4 | 4 | 2 | 9 | 2 | 8 |
| structural portion excluding | | | | | | | |
| thermosetting funcional | | | | | | | |
| group (A) | | | | | | | |
| Type of thermosetting | Glycidyl | Glycidyl | Glycidyl | Glycidyl | Glycidyl | Glycidyl | Glycidyl |
| functional group | ester group | ester group | ester group | ester group | ester group | ester group | ester group |
| Number of thermosettting | 1 | 1 | 1 | 1 | 2 | 1 | 1 |
| functional groups (B) | | | | | | | |
| Number of carbon atoms in | 17 | 17 | 9 | 17 | 24 | 8 | 20 |
| structural portion excluding | | | | | | | |
| thermosetting functional | | | | | | | |
| group (C) | | | | | | | |
| Value of formula: A/(B × C) | 0.471 | 0.235 | 0.434 | 0.118 | 0.188 | 0.250 | 0.400 |
| Number of carbon atoms of | 11 | 15 | 6 | 17 | 11 | 7 | 11 |
| chain having maximum | | | | | | | |
| number of atoms in structural | | | | | | | |
| portion excluding | | | | | | | |
| thermosetting functional group | | | | | | | |
| Number of tert-butyl groups in | 2 | 0 | 1 | 0 | 2 | 0 | 2 |
| structural portion excluding | | | | | | | |
| thermosetting functional group | | | | | | | |
| Proportion of carbon atoms | 65 | 88 | 67 | 100 | 46 | 83 | 55 |
| of chain having maximum | | | | | | | |
| number of atoms in carbon | | | | | | | |
| atoms contained in structural | | | | | | | |
| portion excluding thermosetting | | | | | | | |
| fumctional group (D) | | | | | | | |

TABLE 2

| Type of thermosetting compound | Y1 | Y2 | Y3 |
|---|---|---|---|
| Presence of aromatic ring in | Yes | No | No |
| structural portion excluding | | | |
| thermosetting functional group | | | |
| Presence of branched structure | Yes | Yes | Yes |
| in structural portion excluding | | | |
| thermosetting functional group | | | |
| Number of CH₃ terminals in | 6 | 2 | 2 |
| structural portion excluding | | | |
| thermosetting functional | | | |
| group (A) | | | |
| Type of thermosetting | Glycidyl | Glycidyl | Glycidyl |
| functional group | ether | ether | ether |
| | group | group | group |
| Number of thermosetting | 1 | 2 | 2 |
| functional group (B) | | | |
| Number of carbon atoms in | 15 | 15 | 34 |
| structural portion excluding | | | |
| thermosetting functional | | | |
| group (C) | | | |
| Value of formula: A/(B × C) | 0.400 | 0.067 | 0.029 |
| Number of carbon atoms of | 6 | 3 | 8 |
| chain having maximum number | | | |
| of atoms in structural portion | | | |
| excluding thermosetting | | | |
| functional group | | | |
| Number of tert-butyl groups in | 2 | 0 | 0 |
| structural portion excluding | | | |
| thermosetting functional group | | | |
| Proportion of carbon atoms of | 40 | 20 | 24 |
| chain having maximum number | | | |
| of atoms in carbon atoms | | | |
| contained in structural portion | | | |
| excluding thermosetting | | | |
| functional group (%) | | | |

### (Inorganic Filler)

Silica-containing slurry (silica 75 wt %: “SC4050-HOA” manufactured by Admatechs, average particle diameter: 1.0 μm, aminosilane treatment, cyclohexanone: 25 wt %)

### (Curing Accelerator)

Dimethylaminopyridine (“DMAP” manufactured by Wako Pure Chemical Industries, Ltd.)

(Thermoplastic resin)

Phenoxy resin (“YX6954BH30” manufactured by Mitsubishi Chemical Corporation, solid content: 30 wt %)

Polyimide resin: polyimide resin (synthesized product) prepared in the following Synthesis Example.

### Synthesis Example

In a reaction vessel equipped with a stirrer, a water separator, a thermometer, and a nitrogen gas inlet tube, 300.0 g of tetracarboxylic dianhydride (“BisDA-1000” manufactured by Saudi Basic Industries Corporation) and 665.5 g of cyclohexanone were placed, and the solution in the vessel was heated to 60° C. Then, 89.0 g of dimer diamine (“PRIAMINE1075” manufactured by Croda Japan K.K.) and 54.7 g of 1,3-bisaminomethylcyclohexane (manufactured by Mitsubishi Gas Chemical Company, Inc.) were added dropwise to the solution. Thereafter, 121.0 g of methylcyclohexane and 423.5 g of ethylene glycol dimethyl ether were added, and an imidization reaction was performed at 140° C. over 10 hours to obtain a polyimide solution (nonvolatile content: 26.8 wt). The molecular weight (weight average molecular weight) of the obtained polyimide was 20,000.

### Examples 1 to 19 and Comparative Examples 1 to 3

The components shown in Tables 3 to 5 below were blended in the blending amounts (unit: part by weight in terms of solid content) shown in Tables 3 to 5 below, and stirred at normal temperature until the mixture becomes uniform solution, thus obtaining a resin material.

Preparation of Resin Film:

The obtained resin material was applied onto the release-treated surface of a release-treated PET film (“XG284” manufactured by Toray Industries, Inc., thickness: 25 μm) using an applicator, and then dried in a gear oven at 100° C. for 2 minutes and 30 seconds to volatilize the solvent. In this way, a laminated film (laminated film of a PET film and a resin film) in which a resin film (B-stage film) having a thickness of 40 μm was laminated on a PET film was obtained.

### (Evaluation)

(1) Swelling of Cured Product by Reflow Test after Baking

### (1-1) Substrate Preparation:

Laminating Process and Semi-Curing Treatment:

A double-sided copper-clad laminated plate (CCL substrate) (thickness of copper foil of each surface: 18 μm, thickness of substrate: 0.7 mm, substrate size: 100 mm×100 mm, “MCL-E-679FG(R)” manufactured by Hitachi Chemical Co., Ltd.) was prepared. Both copper foil surfaces of the double-sided copper-clad laminated plate were immersed in “Cz8101” manufactured by MEC Co., Ltd., and the copper foil surfaces were subjected to a roughening treatment. A resin film (B-stage film) side of the laminated film was stacked and laminated on both surfaces of the roughened copper-clad laminated plate using “batch type vacuum laminator MVLP-500-IIA” manufactured by Meiki Co., Ltd. to obtain a laminated structure. The lamination was performed by reducing the pressure for 30 seconds to a pressure of 13 hPa or less, then laminating at 100° C. and a pressure of 0.7 MPa for 30 seconds, and then pressing at 100° C. and a press pressure of 0.8 MPa for 60 seconds. Thereafter, the PET film was peeled off, the obtained laminate was heated at 100° C. for 30 minutes, and then further heated at 180° C. for 30 minutes to semi-cure the resin film. In this way, a laminate in which the semi-cured product of the resin film was laminated on the CCL substrate was obtained.

Roughening Treatment and Desmear Treatment:

(a) Swelling Treatment:

The obtained laminate was placed in a swelling liquid (“Swelling Dip Securiganth P” manufactured by Atotech Japan K.K.) at 60° C., and was shaken for 10 minutes. Thereafter, the laminate was washed with pure water.

(b) Permanganate Treatment (Roughening Treatment and Desmear Treatment):

The laminate after the swelling treatment was placed in a roughing aqueous solution of potassium permanganate (“Concentrate Compact CP” manufactured by Atotech Japan K.K.) at 80° C., and was shaken for 30 minutes. Next, the laminate was treated for 2 minutes using a washing liquid (“Reduction Securiganth P” manufactured by Atotech Japan K.K.) at 25° C., and then washed with pure water to obtain a laminate after desmear treatment.

Electroless Plating Treatment:

The surface of the cured product in the obtained laminate after the desmear treatment was treated with an alkali cleaner (“Cleaner Securiganth 902” manufactured by Atotech Japan K.K.) at 60° C. for 5 minutes, and degreased and washed. After the washing, the cured product was treated with a predip liquid (“Predip Neoganth B” manufactured by Atotech Japan K.K.) at 25° C. for 2 minutes. Thereafter, the cured product was treated with an activator liquid (“Activator Neoganth 834” manufactured by Atotech Japan K.K.) at 40° C. for 5 minutes, and a palladium catalyst was provided thereon. Next, the cured product was treated with a reduction liquid (“Reducer Neoganth WA” manufactured by Atotech Japan K.K.) at 30° C. for 5 minutes.

Next, the cured product was placed in a chemical copper liquid (“Basic Printoganth MSK-DK”, “Kappa Printoganth MSK”, “Stabilizer Printoganth MSK”, and “Reducer Cu” manufactured by Atotech Japan K.K.), and subjected to electroless plating until the plating thickness reached approximately 0.5 μm. After the electroless plating, the cured product was subjected to an annealing treatment at a temperature of 120° C. for 30 minutes in order to remove residual hydrogen gas. All the processes up to the electroless plating process were performed in respective beakers containing 2 L of a treatment liquid while the cured product was shaken.

Electrolysis Plating Treatment:

Next, electrolysis plating was applied to the cured product subjected to the electroless plating treatment until the plating thickness reached 25 μm. A copper sulfate solution (“copper sulfate pentahydrate” manufactured by Wako Pure Chemical Industries, Ltd., “sulfuric acid” manufactured by Wako Pure Chemical Industries, Ltd., “Basic Leveller Cupracid HL” manufactured by Atotech Japan K.K., “Correction Agent Cupracid GS” manufactured by Atotech Japan K.K.) was used as electrolytic copper plating, and electrolysis plating was performed by applying a current of 0.6 A/cm² until the plating thickness reached approximately 25 μm. After the copper plating treatment, the cured product was heated at 200° C. for 90 minutes to further cure the cured product. In this way, a cured product in which the copper plating layer is laminated on the upper surface thereof was obtained.

Baking Treatment:

The obtained cured product in which the copper plating layer is laminated on the upper surface thereof was cut into a 85 mm square, and subjected to a baking treatment at 125° C. to obtain cured products after 1 hour, 2 hours, and 6 hours from the start of the baking treatment. For the obtained cured products, the presence of swelling of the cured product was evaluated. Specifically, the following reflow test was performed.

### (2-2) Reflow Test

Using the cured product on which the copper plating layer after baking treatment was laminated, moisture absorption of the substrate was performed (for 40 hours at a temperature of 60° C. and a humidity of 60 RH %) in accordance with LEVEL 3 of JEDEC. A reflow test (reflow temperature profile conforming to IPC/JEDEC J-STD-020C) was performed using a reflow apparatus (“HAS-6116” manufactured by Nippon Antom Co., Ltd.) that reproduces a solder reflow temperature of 260° C. at peak temperature. The reflow was repeated 10 times. The presence of the occurrence of blisters after reflowing was visually confirmed.

[Determination Criteria for Swelling of Cured Product by Reflow Test after Baking]

∘: No blister occurred after 10 times of reflow.

x: There is blister occurrence in reflow performed 1 to 9 times.

[Overall Evaluation of Swelling of Cured Product by Reflow Test after Baking]

∘∘: The determination result of 1 hour baking is ∘.

∘: The determination result of 2 hours of baking is ∘.

Δ: The determination result of 6 hours of baking is ∘.

x: The determination result of 6 hours of baking is x.

### (2) Warpage of Cured Product

The obtained laminated film was cut into a size of 50 mm×50 mm. The cut laminated film was stacked on a copper plate (50 mm×50 mm×100 μm in thickness) from the resin film side. Then, using a diaphragm type vacuum laminator (“batch type vacuum laminator MVLP-500-IIA” manufactured by Meiki Co., Ltd.), the pressure was reduced for 30 seconds to 13 hPa or less, and then lamination was performed at 100° C. and a pressure of 0.7 MPa for 30 seconds. In this way, a laminate in which a laminated film (an uncured product of a resin film and a PET film) was laminated on a copper plate was obtained.

The PET film was peeled off, and the obtained laminate was heated at 100° C. for 30 minutes and then further heated at 180° C. for 30 minutes. Then, the laminate was heated at 200° C. for 90 min. In this way, a laminate in which a cured product of a resin film was laminated on a copper plate was obtained. The laminate was placed on a piece of flat glass in a manner that the copper plate was on the lower side and the cured product was on the upper side, and the degree of warpage of the four corners was measured. The distance from the upper surface of the flat glass piece to each of the four corners was defined as the amount of warpage, and the average value of the amounts of warpage at the four corners was determined. The warpage of the cured product was determined according to the following criteria.

### [Determination Criteria for Warpage of Cured Product]

∘∘: The average value of amounts of warpage is 3 mm or less.

∘: The average value of amounts of warpage is more than 3 mm and 5 mm or less.

Δ: The average value of amounts of warpage is more than 5 mm and 10 mm or less.

x: The average value of amounts of warpage is more than 10 mm.

### (3) Dielectric Loss Tangent

The obtained resin film was heated at 100° C. for 30 minutes, and then further heated at 180° C. for 30 minutes. The resin film was further heated at 200° C. for 90 minutes to obtain a cured product. The obtained cured product was cut into pieces with a size of 2 mm in width and 80 mm in length, and 10 pieces thereof were stacked to form a stacked body. The dielectric loss tangent of the stacked body was measured at a frequency of 5.8 GHz at normal temperature (23° C.) by a cavity resonance method using “cavity resonance perturbation method dielectric constant measuring apparatus CP521” manufactured by Kanto Electronic Application and Development Inc., and “Network analyzer N5224A PNA” manufactured by Keysight Technologies.

### [Determination Criteria for Dielectric Loss Tangent]

∘: The dielectric loss tangent is 3.5×10⁻³ or less.

Δ: The dielectric loss tangent is more than 3.5×10⁻³ and 4.0×10⁻³ or less.

x: The dielectric loss tangent is more than 4.0×10−3.

The composition and results are shown in Tables 3 to 5 below.

TABLE 3

| | | | | Example | Example | Example | Example | Example | Example | Example | Example | Example |
|---|---|---|---|---|---|---|---|---|---|---|---|---|
| | | | | 1 | 2 | 3 | 4 | 5 | 6 | 7 | 8 | 9 |
| First | | X1 | Part by weight | 5 | | | | | | 10 | | 4.2 |
| thermosetting | | X2 | Part by weight | | 5 | | | | | | | |
| compound | | X3 | Part by weight | | | 5 | | | | | | |
| | | X4 | Part by weight | | | | 5 | | | | | |
| | | X5 | Part by weight | | | | | 5 | | | | |
| | | X6 | Part by weight | | | | | | 5 | | | |
| | | X7 | Part by weight | | | | | | | | 5 | |
| Second | | Y1 | Part by weight | | | | | | | | | |
| thermosetting | | Y2 | Part by weight | | | | | | | | | |
| compound | | Y3 | Part by weight | | | | | | | | | |
| | | Y4 | Part by weight | 5 | 8 | 8 | 5 | 8 | 8 | 35 | 5 | 6.7 |
| | | Y5 | Part by weight | 3 | 3 | 3 | 3 | 3 | 3 | 6 | 3 | 2.5 |
| | | Y6 | Part by weight | 12 | 12 | 12 | 12 | 12 | 12 | 24 | 12 | 10 |
| | | Y7 | Part by weight | 1.4 | 1.4 | 1.4 | 1.4 | 1.4 | 1.4 | 2.8 | 1.4 | 1.1 |
| | | Y8 | Part by weight | | | | | | | | | |
| | | Y9 | Part by weight | | | | | | | | | |
| | | Y10 | Part by weight | | | | | | | | | |
| | | Y11 | Part by weight | | | | | | | | | |
| Inorganic | Silica | SC4050-HOA | Part by weight | 70 | 70 | 70 | 70 | 70 | 70 | 40 | 70 | 75 |
| filler | | | Part by weight | 0.1 | 0.2 | 0.2 | 0.1 | 0.2 | 0.2 | 0.2 | 0.1 | 0.08 |
| Curing | Dimethyl- | | Part by weight | 0.5 | 0.5 | 0.5 | 0.5 | 0.5 | | 2.0 | 0.5 | 0.42 |
| accelerator | amino- | | Part by weight | | | | | | | | | |
| | pyridine | | | | | | | | | | | |
| Thermo- | Phenoxy | YX69548H30 | Part by weight | | | | | | | | | |
| plastic | resin | | | | | | | | | | | |
| resin | Polymide | Synthesized | Part by weight | | | | | | | | | |
| | resin | product | | | | | | | | | | |

| Content of inorganic filler | | wt % | 70 | 70 | 70 | 70 | 70 | 70 | 40 | 70 | 75 |
|---|---|---|---|---|---|---|---|---|---|---|---|
| in 100 wt % of | | | | | | | | | | | |
| components excluding | | | | | | | | | | | |
| solvent in resin material | | | | | | | | | | | |
| Swelling of | Baking time | Determination | ○ | × | ○ | × | × | × | × | ○ | × |
| cured product | 1 hour | | | | | | | | | | |
| by reflex test | Baking time | Determination | ○ | ○ | ○ | × | × | ○ | ○ | ○ | × |
| after baking | 2 hour | | | | | | | | | | |
| | Baking time | Determination | ○ | ○ | ○ | ○ | ○ | ○ | ○ | ○ | ○ |
| | 6 hour | | | | | | | | | | |
| | Overall | Determination | ○○ | ○ | ○○ | Δ | Δ | ○ | ○ | ○○ | Δ |
| | evaluation | | | | | | | | | | |

| | | | | | | | | | | |
|---|---|---|---|---|---|---|---|---|---|---|
| Warpage of cured product | Determination | ○○ | ○ | ○○ | ○ | ○ | ○ | Δ | ○○ | ○○ |
| Dielectric loss tangent | Determination | ○ | ○ | ○ | Δ | ○ | Δ | Δ | ○ | ○ |

TABLE 4

| | | | | Example | Example | Example | Example | Example | Example | Example | Example | Example | Example |
|---|---|---|---|---|---|---|---|---|---|---|---|---|---|
| | | | | 10 | 11 | 12 | 13 | 14 | 15 | 16 | 17 | 18 | 19 |
| First | | X1 | Part by | 0.5 | 1 | 25 | | | | | 5 | 5 | 5 |
| thermosetting | | | weight | | | | | | | | | | |
| compound | | X2 | Part by | | | | 5 | 5 | 5 | 5 | | | |
| | | | weight | | | | | | | | | | |
| | | X3 | Part by | | | | | | | | | | |
| | | | weight | | | | | | | | | | |
| | | X4 | Part by | | | | | | | | | | |
| | | | weight | | | | | | | | | | |
| | | X5 | Part by | | | | | | | | | | |
| | | | weight | | | | | | | | | | |
| | | X6 | Part by | | | | | | | | | | |
| | | | weight | | | | | | | | | | |
| | | X7 | Part by | | | | | | | | | | |
| | | | weight | | | | | | | | | | |
| Second | | Y1 | Part by | | | | | | | | | | |
| thermosetting | | | weight | | | | | | | | | | |
| compound | | Y2 | Part by | | | | | | | | | | |
| | | | weight | | | | | | | | | | |
| | | Y3 | Part by | | | | | | | | | | |
| | | | weight | | | | | | | | | | |
| | | Y4 | Part by | 9.5 | 9.3 | 11.1 | 8 | 8 | 8 | 8 | 8 | 8 | 8 |
| | | | weight | | | | | | | | | | |
| | | Y5 | Part by | 3.5 | 3.5 | 4.2 | 3 | 3 | 7 | 3 | 3 | 3 | 5 |
| | | | weight | | | | | | | | | | |
| | | Y6 | Part by | 14.2 | 14 | 16.6 | | | | 32 | 6 | 6 | 6 |
| | | | weight | | | | | | | | | | |
| | | Y7 | Part by | 1.6 | 1.8 | 1.9 | 1.4 | 1.4 | 1.4 | 1.4 | 1.4 | 1.4 | 1.4 |
| | | | weight | | | | | | | | | | |
| | | Y8 | Part by | | | | 12 | | 6 | | | | |
| | | | weight | | | | | | | | | | |
| | | Y9 | Part by | | | | | 32 | 6 | | | | |
| | | | weight | | | | | | | | | | |
| | | Y10 | Part by | | | | | | | | 6 | | 6 |
| | | | weight | | | | | | | | | | |
| | | Y11 | Part by | | | | | | | | | 6 | |
| | | | weight | | | | | | | | | | |
| Inorganic | Silica | SC4050-HOA | Part by | 70 | 70 | 40 | 70 | 70 | 70 | 40 | 75 | 70 | 70 |
| filler | | | weight | | | | | | | | | | |
| | | | Part by | 0.1 | 0.1 | 0.2 | 0.1 | 0.1 | 0.1 | 0.2 | 0.1 | 0.1 | 0.1 |
| | | | weight | | | | | | | | | | |
| Curing | Dimethyl- | | Part by | 0.5 | 0.5 | 1.0 | 0.5 | 0.5 | 0.5 | | 0.5 | 0.5 | |
| accelerator | amino- | | weight | | | | | | | | | | |
| | pyridine | | Part by | | | | | | | 0.5 | | | 0.5 |
| | | | weight | | | | | | | | | | |
| Thermo- | Phenoxy | YX69548H30 | Part by | | | | | | | | | | |
| plastic | resin | | weight | | | | | | | | | | |
| resin | Polymide | Synthesized | Part by | | | | | | | | | | |
| | resin | product | weight | | | | | | | | | | |

| Content of inorganic filler | | wt % | 70 | 70 | 40 | 70 | 70 | 70 | 70 | 75 | 70 | 70 |
|---|---|---|---|---|---|---|---|---|---|---|---|---|
| in 100 wt % of | | | | | | | | | | | | |
| components excluding | | | | | | | | | | | | |
| solvent in resin material | | | | | | | | | | | | |
| Swelling of | Baking time | Deter- | × | × | × | ○ | ○ | ○ | ○ | × | × | ○ |
| cured product | 1 hour | mination | | | | | | | | | | |
| by reflex test | Baking time | Deter- | × | ○ | × | ○ | ○ | ○ | ○ | ○ | × | ○ |
| after baking | 2 hour | mination | | | | | | | | | | |
| | Baking time | Deter- | ○ | ○ | ○ | ○ | ○ | ○ | ○ | ○ | ○ | ○ |
| | 6 hour | mination | | | | | | | | | | |
| | Overall | Deter- | Δ | ○ | Δ | ○○ | ○○ | ○○ | ○○ | ○ | Δ | ○○ |
| | evaluation | mination | | | | | | | | | | |

| | | | | | | | | | | | |
|---|---|---|---|---|---|---|---|---|---|---|---|
| Warpage of cured product | Deter- | ○ | ○ | Δ | ○ | ○ | ○○ | ○ | ○○ | ○○ | ○○ |
| | mination | | | | | | | | | | |
| Dielectric loss tangent | Deter- | ○ | ○ | ○ | ○ | ○ | ○ | ○ | ○ | ○ | ○ |
| | mination | | | | | | | | | | |

TABLE 5

| | | | | Comparative | Comparative | Comparative |
|---|---|---|---|---|---|---|
| | | | | Example 1 | Example 2 | Example 3 |
| First thermosetting | | X1 | Part by weight | | | |
| compound | | X2 | Part by weight | | | |
| | | X3 | Part by weight | | | |
| | | X4 | Part by weight | | | |
| | | X5 | Part by weight | | | |
| | | X6 | Part by weight | | | |
| | | X7 | Part by weight | | | |
| Second thermosetting | | Y1 | Part by weight | 5 | | |
| compound | | Y2 | Part by weight | | 5 | |
| | | Y3 | Part by weight | | | 5 |
| | | Y4 | Part by weight | 8 | 8 | 8 |
| | | Y5 | Part by weight | 3 | 3 | 3 |
| | | Y6 | Part by weight | 12 | 12 | 12 |
| | | Y7 | Part by weight | 1.4 | 1.4 | 1.4 |
| | | Y8 | Part by weight | | | |
| | | Y9 | Part by weight | | | |
| | | Y10 | Part by weight | | | |
| | | Y11 | Part by weight | | | |
| Inorganic | Silicia | SC4650- | Part by weight | 70 | 70 | 70 |
| filler | | BOA | | | | |
| Curing | Dimethyl- | DAMP | Part by weight | 0.1 | 0.1 | 0.1 |
| accelerator | aminopyridine | | | | | |
| Thermosplastic | Phenoxy resin | XX69548830 | Part by weight | 0.5 | 0.5 | 0.5 |
| resin | Polyimide | Synthesized | Part by weight | | | |
| | resin | product | | | | |

| Content of inorganic filler in 100 wt. % | | wt. % | 70 | 70 | 70 |
|---|---|---|---|---|---|
| of components excluding solvent in | | | | | |
| resin material | | | | | |
| Swelling of | Baking time | Determination | X | X | X |
| cured product | 1 hour | | | | |
| by reflow test | Baking time | Determination | X | X | X |
| after baking | 2 hour | | | | |
| | Baking time | Determination | X | X | X |
| | 6 hour | | | | |
| | Overall | Determination | X | X | X |
| | evaluation | | | | |

| | | | | |
|---|---|---|---|---|
| Warpage of cured producer | Determination | X | Δ | ◯ |
| Dielectric loss tangent | Determination | ◯ | X | ◯ |

1. A resin material comprising:
a thermosetting compound that does not have an aromatic ring in a structural portion excluding a thermosetting functional group, has two or more CH₃ terminals in a structural portion excluding a thermosetting functional group, and satisfies the following formula (X): and
an inorganic filler,
the resin material having a content of the inorganic filler of 30 wt % or more in 100 wt % of components excluding a solvent in the resin material:
0.1≤A/(B×C)≤0.6 Expression (X)
A: number of CH₃ terminals of a structural portion excluding a thermosetting functional group of the thermosetting compound,
B: number of thermosetting functional groups of the thermosetting compound, and
C: number of carbon atoms of a structural portion excluding a thermosetting functional group of the thermosetting compound.

2. The resin material according to claim 1, wherein
the thermosetting compound has a tert-butyl group in a structural portion excluding a thermosetting functional group, and
the thermosetting compound has one or more tert-butyl groups in a structural portion excluding a thermosetting functional group.

3. The resin material according to claim 1, wherein the thermosetting compound has 5 or more and 30 or less carbon atoms in a structural portion excluding a thermosetting functional group.

4. The resin material according to claim 1, wherein the thermosetting compound has one or two thermosetting functional groups.

5. The resin material according to claim 1, wherein the thermosetting compound has one thermosetting functional group.

6. The resin material according to claim 1, wherein the structural portion excluding a thermosetting functional group of the thermosetting compound has a branched structure.

7. The resin material according to claim 1, wherein
the structural portion excluding a thermosetting functional group of the thermosetting compound has a branched structure, and
a proportion of number of carbon atoms of a chain having a maximum number of atoms of the structural portion excluding a thermosetting functional group of the thermosetting compound in 100% of number of carbon atoms of the structural portion excluding a thermosetting functional group of the thermosetting compound is 40% or more and 90% or less.

8. The resin material according to claim 1, wherein the resin material is a resin film.

9. The resin material according to claim 1, wherein the resin material is used for forming an insulating layer in a multilayer printed wiring board.

10. A multilayer printed wiring board comprising:
a circuit board;
a plurality of insulating layers disposed on a surface of the circuit board; and
a metal layer disposed between the plurality of insulating layers,
at least one of the plurality of insulating layers being a cured product of the resin material according to claim 1.
